(19) United States
(12) Patent Application Publication
(10) Pub. No.: US 2025/0290987 A1
(43) Pub. Date: Sep. 18, 2025

(54) INFORMATION PROCESSING APPARATUS AND IMPEDANCE ESTIMATION METHOD

(71) Applicant: Kabushiki Kaisha Toshiba, Tokyo (JP)

(72) Inventors: Ryuji TAKAHASHI, Kawasaki Kanagawa (JP); Nobukatsu SUGIYAMA, Kawasaki Kanagawa (JP)

(21) Appl. No.: 19/067,551

(22) Filed: Feb. 28, 2025

(30) Foreign Application Priority Data
Mar. 15, 2024 (JP) 2024-041671

(51) Int. Cl. G01R 31/367; G01R 31/389; H02J 7/00

(52) U.S. Cl. CPC G01R 31/367; G01R 31/389; H02J 7/0047

(57) ABSTRACT

An information processing apparatus according to an embodiment includes an intra-active material charge carrier distribution calculation unit, a hysteresis variable calculation unit, and an impedance calculation unit. The intra-active material charge carrier distribution calculation unit calculates a charge carrier distribution inside an active material particle included in a secondary battery. The hysteresis variable calculation unit calculates a hysteresis variable representing a voltage characteristic depending on a charge-discharge history of the secondary battery on the basis of the charge carrier distribution. The impedance calculation unit calculates an impedance of the secondary battery on the basis of a first impedance in a first charge-discharge history state, a second impedance in a second charge-discharge history state, and the hysteresis variable.

### CROSS-REFERENCE TO RELATED APPLICATION

This application is based upon and claims the benefit of priority from Japanese Patent Application No. 2024-041671, filed Mar. 15, 2024, the entire contents of which are incorporated herein by reference.

### FIELD

Embodiments of the present invention relate generally to an information processing apparatus and an impedance estimation method.

### BACKGROUND

A battery model capable of expressing impedance characteristics of a battery at high speed and with high accuracy is desired. It is known that a hysteresis phenomenon in which impedance characteristics are different depending on a charge-discharge history occurs in a secondary battery, and an information processing apparatus and an impedance estimation method capable of reproducing impedance characteristics of a secondary battery having a hysteresis characteristic are required.

### BRIEF DESCRIPTION OF THE DRAWINGS

FIG. 1 is an example of an outline diagram of an information processing system 1.

FIG. 2 is an example of a schematic diagram of a distribution of charge carriers in an active material particle.

FIG. 3 is an example of a schematic diagram of a distribution of charge carriers in an active material particle.

FIGS. 4A and B are examples of schematic diagrams each illustrating a change in a charge carrier distribution near a surface of an active material particle in a negative electrode.

FIGS. 5A and B are schematic diagrams each illustrating a relationship between an active material particle and a charge carrier that moves, when charging or discharging is further performed from various charge-discharge histories.

FIG. 6 is a schematic diagram illustrating a relationship between an active material particle and a charge carrier that moves, when charging or discharging is further performed from a predetermined charge-discharge history.

FIG. 7 is an example of a flowchart of hysteresis variable calculation.

FIG. 8 is a foster-type equivalent circuit model.

FIGS. 9A and B are graphs each illustrating a temporal change in overvoltage.

FIG. 10 is an example of an outline diagram of an information processing system.

### DETAILED DESCRIPTION

An information processing apparatus according to an embodiment includes an intra-active material charge carrier distribution calculation unit, a hysteresis variable calculation unit, and an impedance calculation unit. The intra-active material charge carrier distribution calculation unit calculates a charge carrier distribution inside an active material particle included in a secondary battery. The hysteresis variable calculation unit calculates a hysteresis variable representing a voltage characteristic depending on a charge-discharge history of the secondary battery on the basis of the charge carrier distribution. The impedance calculation unit calculates an impedance of the secondary battery on the basis of a first impedance in a first charge-discharge history state, a second impedance in a second charge-discharge history state, and the hysteresis variable.

Hereinafter, embodiments will be described with reference to the drawings. Note that, hereinafter, the same or similar reference numerals will be given to the same or similar elements as those already described, and redundant descriptions will be basically omitted. In addition, the drawings are schematic or conceptual, and a relationship between a thickness and a width of each portion, a ratio coefficient of a size between the portions, and the like that are illustrated are not necessarily the same as actual ones. In addition, even in a case of representing the same portion, dimensions and ratio coefficients may be represented differently in different drawings.

### First Embodiment

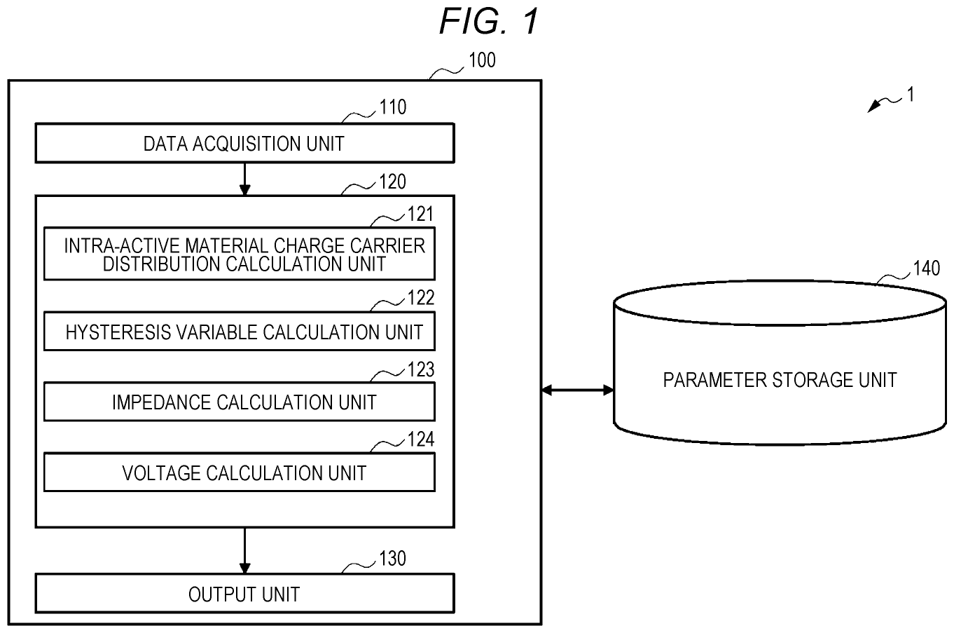

FIG. 1 is an example of an outline diagram of an information processing system 1 according to the present embodiment. As illustrated in FIG. 1, the information processing system 1 includes an information processing apparatus 100 and a parameter storage unit 140 that stores parameters related to information processing performed by the information processing apparatus 100. The information processing apparatus 100 includes a data acquisition unit 110, an estimation unit 120, and an output unit 130.

The information processing apparatus 100 is, for example, a processing apparatus (computer) such as a server, and can communicate with the parameter storage unit 140 via a wired or wireless network.

The data acquisition unit 110 can correspond to, for example, an input/output interface (I/F), a communication I/F, and the like, and a processor. Here, the processor is typically a central processing unit (CPU) and/or a graphics processing unit (GPU), but may be a microcomputer, a field programmable gate array (FPGA), a digital signal processor (DSP), another general-purpose or dedicated processor, or the like.

The data acquisition unit 110 acquires input data including a measured value of at least one of a current or a voltage of a target secondary battery. The input data may be acquired directly from a measuring instrument such as an ammeter, for example, or may be acquired by wired/wireless communication from a remote controller of the secondary battery, for example. A current, a voltage, and/or power may be measured over a plurality of time points during charging and/or discharging of the secondary battery. Further, the input data may include temperature data. The temperature data may indicate a measured value of a temperature of the target secondary battery and/or an ambient temperature around the secondary battery. The current/voltage/power/temperature data may have a value indicating time of measurement, in addition to the current/voltage/power/temperature measured value. The data acquisition unit 110 writes the input data into the parameter storage unit 140.

The estimation unit 120 can correspond to, for example, a processor. The estimation unit 120 reads input data, a function, a fixed parameter, previous calculation results obtained by various calculation units, and the like from the parameter storage unit 140. The estimation unit 120 estimates a voltage of the target secondary battery on the basis of the read data. Details of the voltage estimation by the estimation unit 120 will be described later. The estimation unit 120 writes the estimated voltage into the parameter storage unit 140.

The output unit 130 is, for example, an input/output interface (I/F), a communication I/F, or the like. The output unit 130 reads a voltage of the secondary battery estimated by the estimation unit 120 from the parameter storage unit 140, and outputs the voltage. Here, the outputting may be performed by presentation with an output device, for example, a display, a speaker, or the like, in a form of text, video, audio, or the like, for example, or may be transmitted to an external device. In addition, the output unit 130 may automatically output the voltage of the secondary battery estimated by the estimation unit 120, or may output the voltage in response to a request from a user.

The parameter storage unit 140 can correspond to, for example, a memory, an auxiliary storage device, or the like. Here, the auxiliary storage device may be a hard disk drive (HDD), a solid state drive (SSD), another semiconductor memory, or the like.

Input data is written into the parameter storage unit 140 by the data acquisition unit 110. In the parameter storage unit 140, various functions (may be curve data or a look up table (LUT)) to be described later, fixed parameters (for example, an upper limit voltage and a lower limit voltage to be described later, and an initial value of each parameter), and the like to be used for voltage estimation by the estimation unit 120 are written in advance. Further, the voltage is written in the parameter storage unit 140 by the estimation unit 120. Data such as the voltage stored in the parameter storage unit 140 is read by the output unit 130.

Hereinafter, details of the voltage estimation by the estimation unit 120 will be described.

First, definitions of a battery capacity and a state of charge (SOC) in the present specification will be described. Note that, in general, a capacity of the lithium ion secondary battery is calculated on the basis of an upper limit voltage determined at the time of charging and a lower limit voltage determined at the time of discharging. However, in the present specification, a capacity of the secondary battery is defined on the basis of an open circuit voltage (OCV) of the secondary battery. Specifically, a charge capacity at the time when the secondary battery is charged until the OCV reaches a predetermined upper limit voltage from a predetermined lower limit voltage or a discharge capacity at the time when the secondary battery is discharged until the OCV reaches a lower limit voltage from an upper limit voltage is defined as the capacity of the secondary battery. In the present specification, the SOC of the secondary battery is a ratio of a charge amount of the secondary battery to the capacity of the secondary battery, when the SOC with the OCV being the lower limit voltage is set to 0[%] and the SOC with the OCV being the upper limit voltage is set to 100[%].

The estimation unit 120 estimates a voltage for every unit time. The estimation unit 120 can include: an intra-active material charge carrier distribution calculation unit 121 that calculates a charge carrier distribution inside an active material particle included in the secondary battery; a hysteresis variable calculation unit 122 that calculates a hysteresis variable representing a voltage characteristic depending on a charge-discharge history of the secondary battery on the basis of the charge carrier distribution; an impedance calculation unit 123 that calculates an impedance of the secondary battery on the basis of a first impedance in a first charge-discharge history state, a second impedance in a second charge-discharge history state, and the hysteresis variable; and a voltage calculation unit 124 that calculates a voltage of the secondary battery on the basis of the impedance of the secondary battery and a current flowing through the secondary battery.

The intra-active material charge carrier distribution calculation unit 121 calculates a distribution (hereinafter, referred to as “intra-active material charge carrier distribution”) of charge carriers inside the active material particle of the target secondary battery for every unit time. Specifically, on the basis of an intra-active material charge carrier distribution model representing the charge carrier distribution in the active material at a first time point, a time difference from the first time point to a second time point which is after the first time point, and input data of at least one of a current or a voltage, an intra-active material charge carrier distribution model at the second time point is calculated.

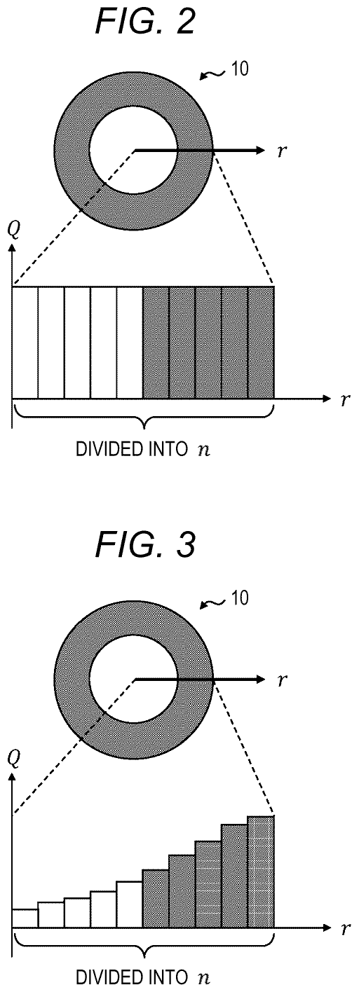

FIG. 2 is an example of a schematic diagram of a distribution of charge carriers in an active material particle 10. Here, for simplicity, a two-dimensional distribution will be described as an example. In the figure, a gray portion is a region where charge carriers exist. FIG. 2 illustrates an example in which charge carriers exist near an outer shell of the active material particle 10. In a lower portion of the schematic diagram of the active material particle 10, a horizontal axis represents a distance r from a center of the active material particle 10, and a vertical axis represents a charge capacity Q. FCC is a full charge capacity of the battery, and n is the number of divisions on a two-dimensional distribution horizontal axis, and an upper limit value on the vertical axis may be FCC/n. At this time, an area of a gray portion divided by the FCC corresponds to the SOC. Note that, in order to obtain a more detailed model, as illustrated in FIG. 3, a two-dimensional distribution may be considered in which an upper limit value of the vertical axis varies depending on the distance r from the center of the active material particle 10.

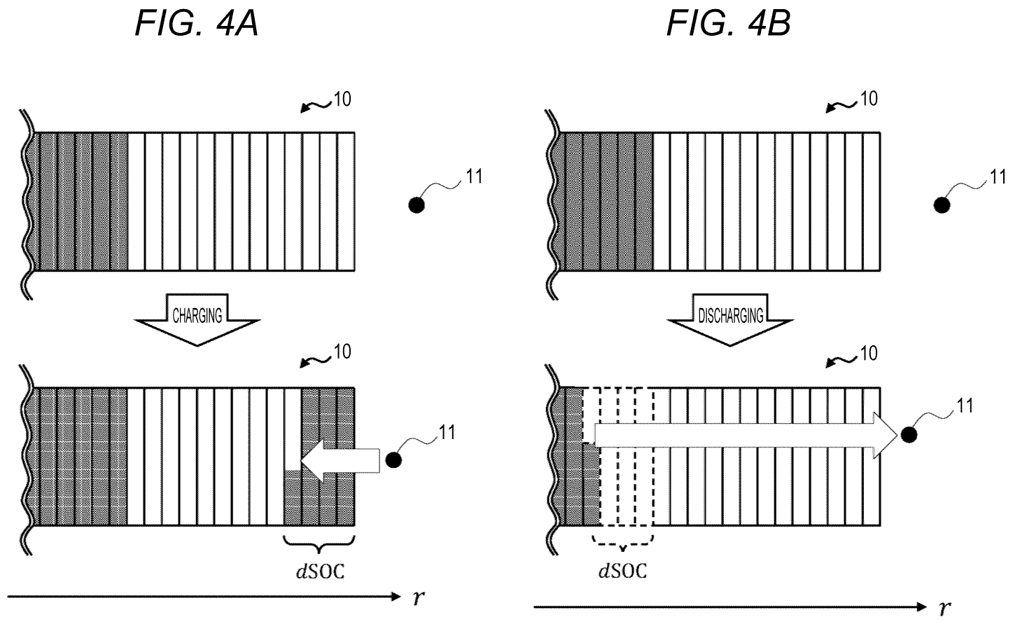

FIG. 4 is an example of a schematic diagram illustrating a change in a charge carrier distribution near a surface of the active material particle 10 in a negative electrode. Similarly to FIG. 2, a gray portion is a region where charge carriers 11 exist. FIG. 4(a) illustrates a change during charging of the secondary battery. At the time of charging, it can be assumed that the charge carriers 11 are inserted sequentially into a void region nearest to the surface of the active material particle 10, among void regions in which the charge carriers 11 of the active material particle 10 do not exist in the active material particle 10. When charging is started from the state illustrated in the upper diagram of FIG. 4(a) and charging is continued for a certain period of time, the charge carriers 11 are distributed and accommodated on the surface of the active material particle 10 as illustrated in the lower diagram of FIG. 4(a). Whereas, FIG. 4(b) illustrates a change during discharging of the secondary battery. At the time of discharging, it can be assumed that the charge carriers 11 are extracted sequentially in order from the charge carrier 11 nearest to the surface of the active material particle 10 among the charge carriers 11 existing in the active material particle 10. When discharging is started from the state of the upper diagram of FIG. 4(b) and discharging is continued for a certain period of time, the state illustrated in the lower diagram of FIG. 4(b) is obtained. In the lower diagram of FIG. 4(b), a dotted line indicates a portion where the charge carrier 11 is removed during this period. As described above, the intra-active material charge carrier distribution model is updated by inserting the charge carriers 11 into the void region nearest to the surface of the active material particle 10 among the void regions of the active material particle 10 at the time of charging the secondary battery, and extracting the charge carrier 11 in order from the charge carrier 11 nearest to the surface of the active material particle 10 among the charge carriers 11 existing in the active material particle 10 at the time of discharging the secondary battery. Hereinafter, in the present specification, the void region nearest to the surface of the active material particle 10 among the void regions of the active material particle 10 will be described as a “void nearest to the surface”, and the charge carrier 11 nearest to the surface of the active material particle 10 among the charge carriers 11 existing in the active material particle 10 will be described as a “charge carrier 11 nearest to the surface”. Note that positions of the void and the charge carrier 11 nearest to the surface are variable depending on the charge/discharge state.

The intra-active material charge carrier distribution calculation unit 121 in the present embodiment can calculate and update a charge carrier distribution model inside the active material particle 10 on the basis of a current value given by measurement or the like. Specifically, first, an SOC change amount dSOC from the first time point to the second time point is calculated by using the following Equation (1).

$$dSOC = \frac{i \cdot dt}{FCC} \qquad [ Formula 1 ]$$

Here, i is a current, dt is a time difference from the first time point to the second time point, and FCC is a full charge capacity of the battery. The intra-active material charge carrier distribution calculation unit 121 updates the intra-active material charge carrier distribution model on the basis of the obtained SOC change amount dSOC and a sign of the current. By adding the charge carriers 11 to the void nearest to the surface by an amount corresponding to the dSOC when the sign of a current i is positive (charge), and deleting the charge carriers 11 nearest to the surface by an amount corresponding to the dSOC, the intra-active material charge carrier distribution model is updated. The updated intra-active material charge carrier distribution model is output to the hysteresis variable calculation unit 122.

The hysteresis variable calculation unit 122 calculates a hysteresis variable on the basis of the intra-active material charge carrier distribution model. In the present embodiment, it is assumed that hysteresis of a voltage characteristic occurs due to a difference in diffusion of the charge carriers 11 due to a difference in the intra-active material charge carrier distribution model. The hysteresis variable calculation unit 122 calculates a hysteresis variable on the basis of a distance by which the charge carriers 11 move inside the active material particle 10 during charging and discharging of the secondary battery. Specifically, it has been assumed that a diffusion resistance at the time of charging is proportional to ease of accommodating the charge carriers 11 in the active material particle 10, and this is proportional to a “distance between the surface and the void portion nearest to the surface”. In addition, it has been assumed that a diffusion resistance at the time of discharging is proportional to ease of releasing the charge carriers 11 in the active material particle 10, and this is proportional to a “distance between the surface and the charge carrier 11 nearest to the surface”. Based on the above, an amount related to the “distance between the surface and the void portion nearest to the surface” at the time of charging and an amount related to the “distance between the surface and the charge carrier 11 nearest to the surface” at the time of discharging are calculated from the intra-active material charge carrier distribution model, and are used as a hysteresis variable.

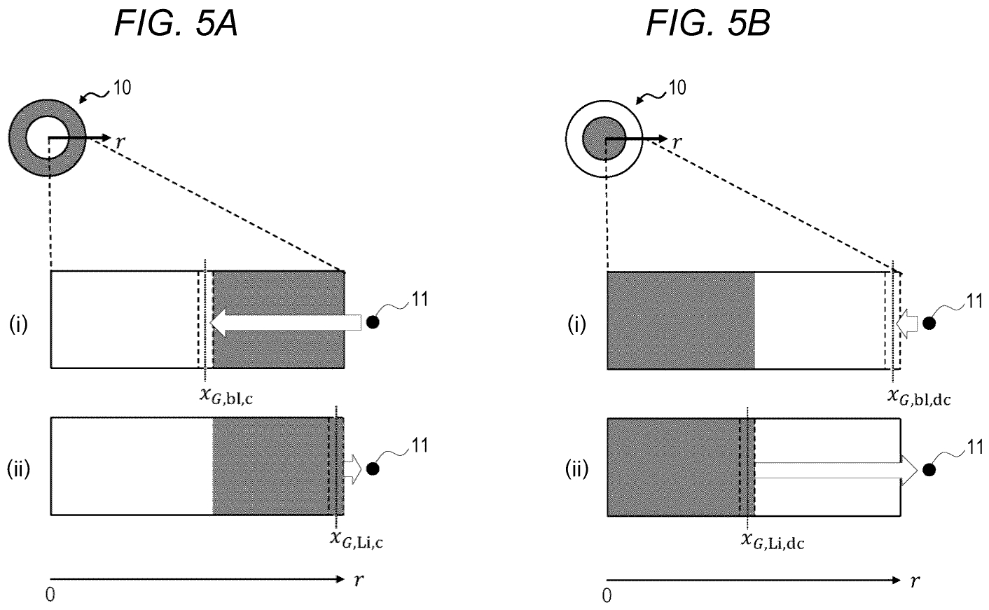

FIG. 5 is a schematic diagram illustrating a relationship between the active material particle 10 and the charge carrier 11 that moves, when charging or discharging is further performed from various charge-discharge histories. Similarly to FIG. 4, a gray portion is a region where the charge carriers 11 exist. FIG. 5(a) conceptually illustrates a movement of the charge carrier 11 in a case where the secondary battery is further charged or discharged from a state where the secondary battery has been charged to be adjusted to any amount of charge (charge adjustment state) from a state where an amount of charge is SOC=0%. In FIG. 5(a), (i) illustrates a case where charging is further performed from the charge adjustment state. At this time, since the “void portion nearest to the surface” is separated from the surface, the active material particle 10 does not easily accommodate the charge carrier 11. That is, the diffusion resistance at the time of charging increases. In FIG. 5(a), (ii) illustrates a case where discharging is performed from the charge adjustment state. At this time, since the “charge carrier 11 nearest to the surface” is present on the surface of the active material particle 10, the active material particle 10 easily releases the charge carrier 11. That is, the diffusion resistance at the time of discharging decreases.

FIG. 5(b) conceptually illustrates a movement of the charge carrier 11 in a case where the secondary battery is further charged or discharged from a state where the secondary battery has been discharged to be adjusted to any amount of charge (discharge adjustment state) from a state where an amount of charge is SOC=100%. In FIG. 5(b), (i) illustrates a case where charging is performed from the discharge adjustment state. At this time, since the “void portion nearest to the surface” exists on the surface, the active material particle 10 easily accommodates the charge carrier 11. That is, the diffusion resistance at the time of charging decreases. In FIG. 5(b), (ii) illustrates a case where discharging is further is performed from the discharge adjustment state. At this time, since the “charge carrier 11 nearest to the surface” is separated from the surface, the active material particle 10 does not easily release the charge carrier 11. That is, the diffusion resistance at the time of discharging increases.

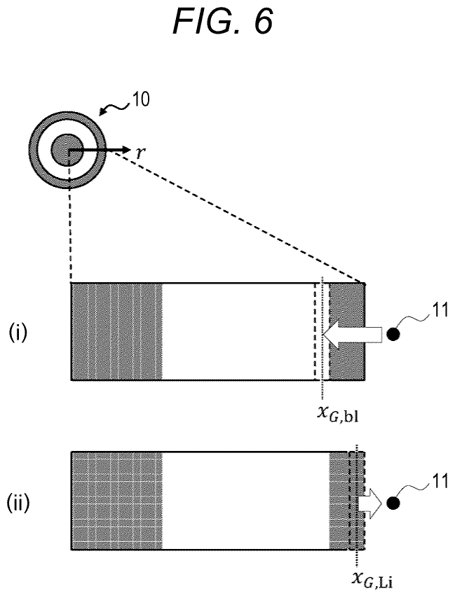

Hereinafter, a method of calculating a hysteresis variable in a state of the intra-active material charge carrier distribution model as illustrated in FIG. 6 will be specifically described. FIG. 6 illustrates an intra-active material charge carrier distribution model after charging to SOC=100%, then discharging to a predetermined charge amount, and further charging of a predetermined amount, but the intra-active material charge carrier distribution model to which the hysteresis variable calculation method described later can be applied is not limited thereto. In FIG. 6, a barycentric position of the voids corresponding to SOCmbl % nearest to the surface is xG,bl. In addition, a barycentric position of the charge carriers 11 corresponding to SOCmLi % nearest to the surface is xG,Li.

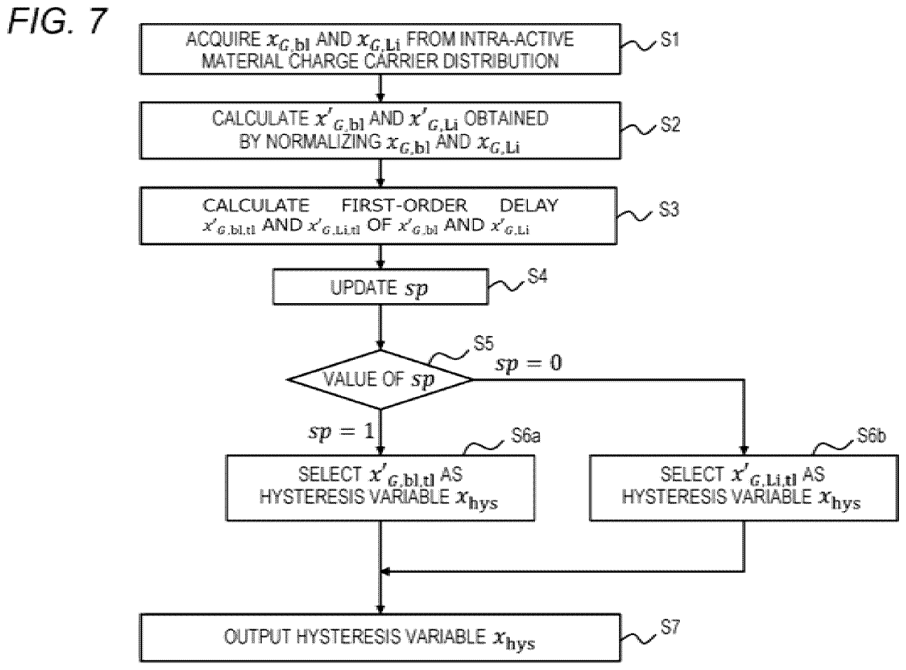

FIG. 7 is an example of a flowchart of hysteresis variable calculation.

First, in S1, the barycentric position xG,bl and the barycentric position xG,Li are acquired on the basis of the intra-active material charge carrier distribution model calculated by the intra-active material charge carrier distribution calculation unit 121.

Next, in S2, the acquired xG,bl and xG, Li are individually normalized so as to be 1 at the time of the charge adjustment and 0 at the time of the discharge adjustment. By using the following Equations (2) and (3), x′G,bl and x′G,Li which are values obtained by normalizing xG,bl and xG,Li, are calculated.

$$\begin{matrix}{x}_{G , b l}^{′} = \frac{{x}_{G , bl , d c} - {x}_{G , bl}}{{x}_{G , bl , d c} - {x}_{G , bl , c}} & [ Formula 2 ] \\ {x}_{G , Li}^{′} = 1 - \frac{{x}_{G , Li , c} - {x}_{G , Li}}{{x}_{G , Li , c} - {x}_{G , Li , d c}} & [ Formula 3 ]\end{matrix}$$

Here, xG,bl,c and xG,bl,dc are xG,bl in the charge adjustment and the discharge adjustment, respectively, and xG,Li,c and xG,Li,dc are xG,Li in the charge adjustment and the discharge adjustment, respectively. x′G,bl and x′G,Li are 1 at the time of the charge adjustment and 0 at the time of the discharge adjustment.

Next, in S3, respective first-order delays x′G,bl.tl and x′G,Li,tl of x′G,bl and x′G,Li are calculated using the following Equations (4) and (5).

$$\begin{matrix}{x}_{G , bl , tl}^{′} ( t ) = {x}_{G , bl , tl}^{′} ( t - dt ) + \frac{- {x}_{G , bl , tl}^{′} ( t - dt ) + {x}_{G , bl}^{′} ( t )}{{τ}_{bl}} dt & [ Formula 4 ] \\ {x}_{G , Li , tl}^{′} ( t ) = {x}_{G , Li , tl}^{′} ( t - dt ) + \frac{- {x}_{G , Li , tl}^{′} ( t - dt ) + {x}_{G , Li}^{′} ( t )}{{τ}_{Li}} dt & [ Formula 5 ]\end{matrix}$$

Here, τbl and τLi are time constants related to a change rate of x′G,bl and x′G,Li with respect to a change in the intra-active material charge carrier distribution model. Note that, x′G,bl (t), x′G,Li(t), x′G,bl.tl (t), and x′G,Li,tl (t) in the equation are notations indicating that x′G,bl, x′G,Li, x′G,bl.tl, and x′G,Li,tl are functions of t, respectively, and the same applies to the following equation.

Next, in S4, a value of a switching parameter sp for determining charge and discharge is determined. For example, when sp=0 and i(t)>0 are satisfied, it may simply be determined that a discharge state or a non-energized state after discharging has changed to a charge state, and sp may be determined as sp=1. Further, when sp=1 and i(t)<0 are satisfied, it may simply be determined that a charge state or a non-energized state after charging has changed to a discharge state, and sp may simply be determined as sp=0.

Next, in S5, the value of sp is determined. Here, in a case where sp=1 is satisfied, it is determined that charging is being performed, the process proceeds to S6a, and x′G,bl.tl is selected as a hysteresis variable xhys. Alternatively, when sp=0 is satisfied, it is determined that discharging is being performed, the process proceeds to S6b, and x′G,Li,tl is selected as the hysteresis variable xhys.

Finally, in S7, the hysteresis variable xhys calculated above is output to the impedance calculation unit 123.

The impedance calculation unit 123 calculates an impedance of the secondary battery on the basis of a first impedance in a first charge-discharge history state, a second impedance in a second charge-discharge history state, and the hysteresis variable. In the present specification, a description will be given on the assumption that the first charge-discharge history state is the charge adjustment state, and the second charge-discharge history state is the discharge adjustment state. Further, a description will be given on the assumption that the first impedance is a value estimated from measurement data in the first charge-discharge history state, and the second impedance is a value estimated from measurement data in the second charge-discharge history state. Further, the impedance is expressed by a resistance and an electrostatic capacitance. A resistance Rc in the charge adjustment state is estimated on the basis of measurement data of at least one of a current or a voltage in the charge adjustment state, and a resistance Rdc in the discharge adjustment state is estimated on the basis of measurement data of at least one of a current or a voltage in the discharge adjustment state. On the basis of the resistance Rc, the resistance Rdc, and the hysteresis variable xhys obtained by the hysteresis variable calculation unit 122, the impedance calculation unit 123 calculates a resistance R of an equivalent circuit model of the secondary battery in any charge-discharge history state. In addition, an electrostatic capacitance Cc in the charge adjustment state is estimated on the basis of measurement data of at least one of a current or a voltage in the charge adjustment state, and an electrostatic capacitance Cdc in the discharge adjustment state is estimated on the basis of measurement data of at least one of a current or a voltage in the discharge adjustment state. On the basis of the electrostatic capacitance Cc, the electrostatic capacitance Cdc, and the hysteresis variable xhys, the impedance calculation unit 123 calculates an electrostatic capacitance C of the equivalent circuit model of the secondary battery in any charge-discharge history state. The impedance calculation unit 123 may use the following Equation (6) for calculating the resistance R and the following Equation (7) for calculating the electrostatic capacitance C.

$$\begin{matrix}R = {x}_{h y s} ( t ) \cdot {R}_{c} + ( 1 - {x}_{h y s} ( t ) ) \cdot {R}_{d c} & [ Formula 6 ] \\ C = {x}_{h y s} ( t ) \cdot {C}_{c} + ( 1 - {x}_{h y s} ( t ) ) \cdot {C}_{d c} & [ Formula 7 ]\end{matrix}$$

Here, the numerical values such as R and C used in the equations have been stored in the parameter storage unit 140.

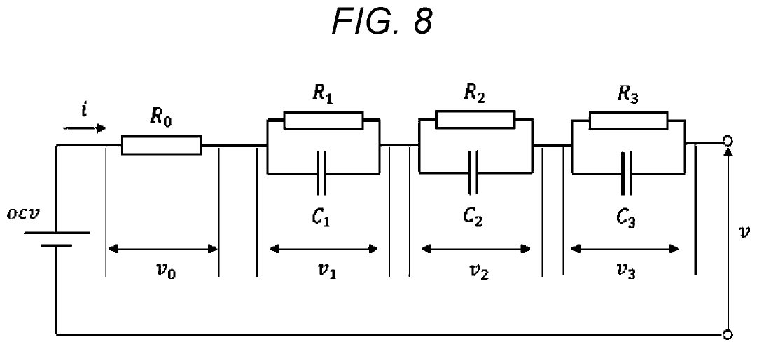

Using the current i, and the resistance R and the electrostatic capacitance C obtained by the impedance calculation unit 123, the voltage calculation unit 124 calculates a voltage v on the basis of the equivalent circuit model in which the impedance is expressed by the resistance and the electrostatic capacitance. For example, a foster-type equivalent circuit model as illustrated in FIG. 8 is considered. At this time, a voltage v (t) at time t is given by using the following Equations (8) to (10).

$$\begin{matrix}v ( t ) = OCV ( SOC ) + {v}_{0} ( t ) + {v}_{1} ( t ) + {v}_{2} ( t ) + {v}_{3} ( t ) & [ Formula 8 ] \\ {v}_{0} ( t ) = {R}_{0} i ( t ) & [ Formula 9 ] \\ \frac{d {v}_{j} ( t )}{d t} = - \frac{{v}_{j} ( t )}{{R}_{j} {C}_{j}} + \frac{i ( t )}{{C}_{j}} \\ j = 1 , 2 , 3 & [ Formula 10 ]\end{matrix}$$

Here, OCV is an open circuit voltage of the battery. For example, a relationship between the SOC and the OCV may be acquired in advance, and the OCV may simply be given to the SOC at each time. As a method for calculating the SOC, a current integration method expressed by using the following Equation (11) or the like may simply be used.

$$SOC ( t ) = {SOC}_{0} + {\int }_{0}^{t} \frac{i ( t )}{FCC} dt \qquad [ Formula 11 ]$$

Here, SOCO is the SOC at time t=0.

Note that, although the example of the foster-type equivalent circuit model has been described above, any equivalent circuit model may be used. To estimate the resistance R and the electrostatic capacitance C in the charge adjustment and the discharge adjustment provided in the parameter storage unit 140, the same equivalent circuit model as that used in the voltage calculation unit 124 may simply be used.

As described above, by considering hysteresis of overvoltage on the basis of the charge-discharge history, the voltage of the secondary battery can be accurately estimated in a relatively short time. Note that the information processing apparatus 100 described above is particularly suitable when the voltage calculation unit 124 calculates the voltage of the secondary battery on the basis of the equivalent circuit model including an overvoltage model of the secondary battery.

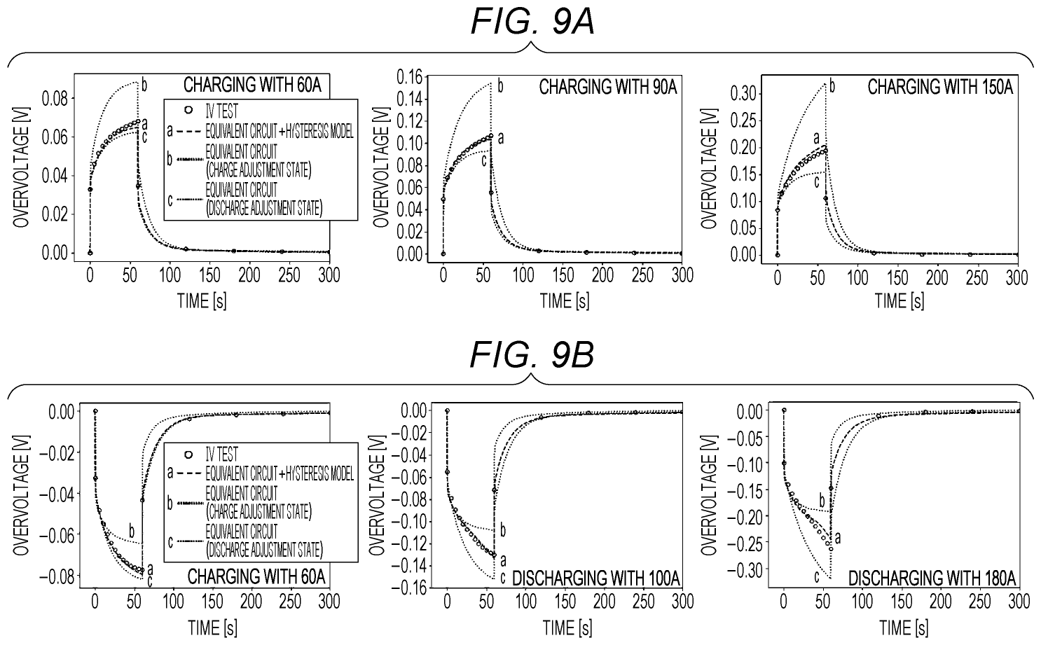

Hereinafter, IV test data and a voltage estimation model according to the present embodiment are compared and shown. FIG. 9 is a graph illustrating a temporal change in overvoltage. A vertical axis represents overvoltage, and a horizontal axis represents time elapsed from a start of charging and discharging. FIG. 9(a) is a graph illustrating a temporal change in overvoltage when charging is performed for 60 seconds with i=60, 90, and 150 A, and FIG. 9(b) is a graph illustrating a temporal change in overvoltage when discharging is performed for 60 seconds with i=60, 100, and 180 A. The IV test data is plotted in white, a broken line a indicates an estimation result obtained by applying the hysteresis variable of the voltage estimation model according to the present embodiment to the equivalent circuit, a dotted line b indicates an estimation result obtained by applying the charge adjustment of the voltage estimation model according to the present embodiment to the equivalent circuit, and a dotted line c indicates an estimation result obtained by applying the discharge adjustment of the voltage estimation model according to the present embodiment to the equivalent circuit. The secondary battery used in the IV test has a certain charge-discharge history (hysteresis). In FIG. 9, it can be seen that the plotting in white indicating the IV test data is in good agreement with the broken line a indicating the estimation result obtained by applying the hysteresis variable of the voltage estimation model according to the present embodiment to the equivalent circuit.

Note that, in the present embodiment, the charge-discharge history serving as the reference is described as the charge adjustment state and the discharge adjustment state. However, the charge-discharge history serving as the reference is not limited thereto and is only required to be two different charge-discharge histories, and these charge-discharge histories can be individually set to a first charge-discharge history state and a second charge-discharge history state.

Note that, in the present embodiment, it has been described that the first and second impedances are values estimated from measurement data in the first and second charge-discharge history states, but the first and second impedances are not limited thereto. For example, values acquired from an external server or the like may be used.

Note that, in the description of the present embodiment, the capacity of the secondary battery is defined based on the OCV, but the OCV may not necessarily be used as the reference. For example, the capacity of the secondary battery may be defined based on a value obtained by adding overvoltage to the OCV.

Note that, in the present embodiment, it is assumed that the diffusion resistance at the time of charging and discharging depends on ease of releasing the charge carriers 11 from the active material particle 10 or ease of accommodating the charge carriers 11 in the active material particle 10. In the embodiment described above, the example focusing on the active material particle of the negative electrode has been described, but similar voltage estimation may be performed focusing on the positive electrode.

### Second Embodiment

In the present embodiment, an information processing apparatus 200 performs hysteresis voltage estimation in consideration of battery degradation.

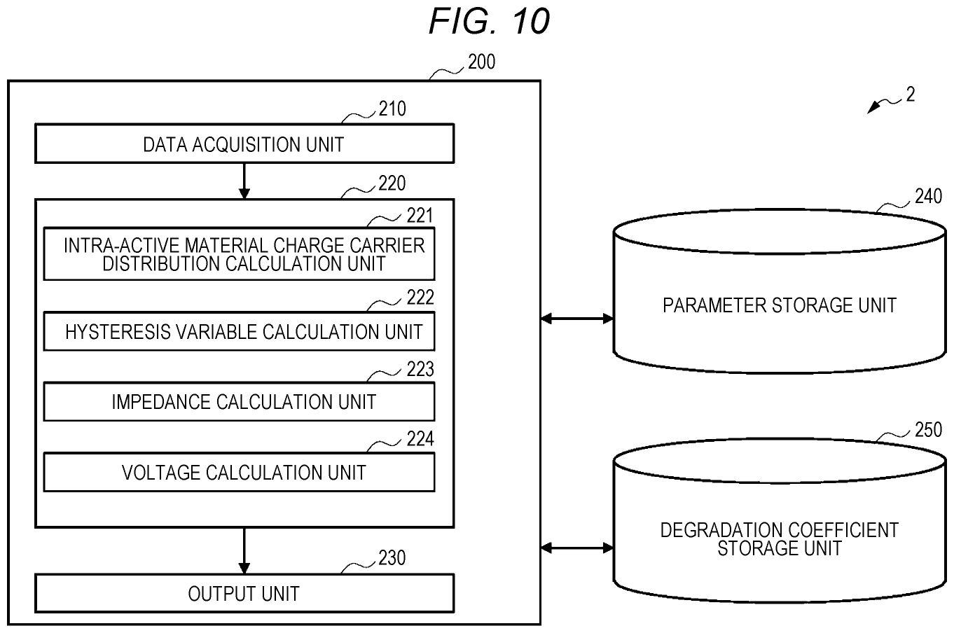

FIG. 10 is an example of an outline diagram of an information processing system 2 according to the present embodiment. As illustrated in FIG. 10, the information processing system 2 includes the information processing apparatus 200, a storage unit 240, and a degradation coefficient storage unit 250. The information processing apparatus 200 includes a data acquisition unit 210, an estimation unit 220, and an output unit 230.

The estimation unit 220 reads input data, a degradation coefficient, a function, a fixed parameter, an estimated voltage, and the like from the storage unit 240 and the degradation coefficient storage unit 250. The estimation unit 220 estimates a voltage of the target secondary battery on the basis of the read data. Details of the voltage estimation by the estimation unit 220 will be described later. The estimation unit 220 writes the estimated voltage into the storage unit 240.

The estimation unit 220 can include an intra-active material charge carrier distribution calculation unit 221, a hysteresis variable calculation unit 222, an impedance calculation unit 223, and a voltage calculation unit 224.

Similarly to the intra-active material charge carrier distribution calculation unit 121, the intra-active material charge carrier distribution calculation unit 221 calculates an intra-active material charge carrier distribution model of the target secondary battery for every unit time.

The hysteresis variable calculation unit 222 calculates a hysteresis variable xhys, similarly to the hysteresis variable calculation unit 122.

The impedance calculation unit 223 calculates an impedance of the secondary battery on the basis of a degradation coefficient related to a degradation state of the secondary battery. That is, the impedance calculation unit 223 can calculate a resistance R and an electrostatic capacitance C in consideration of the degradation state of the secondary battery. For calculating the resistance in consideration of the degradation of the secondary battery, the following Equation (12) can be used.

$${R}_{deg} = ( {x}_{hys} ( t ) \cdot {R}_{c} + ( 1 - {x}_{hys} ( t ) ) \cdot {R}_{d c} ) \cdot {x}_{deg} \qquad [ Formula 12 ]$$

Here, xdeg is a degradation coefficient of the resistance R. For example, xdeg is stored in the degradation coefficient storage unit 250, and the degradation coefficient xdeg may simply be changed according to an index representing a degradation state such as SOH of the secondary battery. When a change rate in the resistance due to degradation is different between Rc and Rdc, different degradation coefficients xc_deg and xdc_deg may simply be applied to Rc and Rdc, respectively. (Equation (13))

$${R}_{deg} = {x}_{hys} ( t ) \cdot {R}_{c} \cdot {x}_{c\_deg} + ( 1 - {x}_{hys} ( t ) ) \cdot {R}_{d c} \cdot {x}_{dc\_deg} \qquad [ Formula 13 ]$$

In addition, degradation of the electrostatic capacitance can be similarly considered.

The voltage calculation unit 224 calculates an estimated value of a voltage v on the basis of a current i, and the resistance R and the electrostatic capacitance C obtained by the impedance calculation unit 223.

In this manner, the impedance calculation unit 223 calculates the resistance R and the electrostatic capacitance C in consideration of a degree of degradation of the secondary battery, and the voltage calculation unit 224 calculates the estimated value of the voltage v by using these values, whereby the information processing apparatus 200 can perform hysteresis voltage estimation in consideration of battery degradation.

Although some embodiments have been described above, the present invention is not limited to the embodiments described above as they are, and can be embodied by modifying the components without departing from the gist thereof in the implementation stage. Furthermore, various inventions can be formed by appropriately combining the plurality of components disclosed in the embodiments described above. For example, some components may be deleted from all the components illustrated in the embodiments. Moreover, the components of different embodiments may be appropriately combined.

### [Supplementary Note 1]

An information processing apparatus including:
an intra-active material charge carrier distribution calculation unit that
calculates a charge carrier distribution inside an active material particle included in a secondary battery;
a hysteresis variable calculation unit that calculates a hysteresis variable representing a voltage characteristic depending on a charge-discharge history of the secondary battery on the basis of the charge carrier distribution; and
an impedance calculation unit that calculates an impedance of the secondary battery on the basis of a first impedance in a first charge-discharge history state, a second impedance in a second charge-discharge history state, and the hysteresis variable.

### [Supplementary Note 2]

The information processing apparatus according to Supplementary note 1, including:
a voltage calculation unit that calculates a voltage of the secondary battery on the basis of an impedance of the secondary battery and a current flowing through the secondary battery.

### [Supplementary Note 3]

The information processing apparatus according to Supplementary note 2, in which
the voltage calculation unit calculates a voltage of the secondary battery on the basis of an equivalent circuit model in which the impedance is expressed by a resistance and an electrostatic capacitance.

### [Supplementary Note 4]

The information processing apparatus according to any one of Supplementary notes 2 and 3, in which
the voltage calculation unit calculates a voltage of the secondary battery on the basis of an equivalent circuit model including an overvoltage model of the secondary battery.

### [Supplementary Note 5]

The information processing apparatus according to any one of Supplementary notes 1 to 4, in which
the intra-active material charge carrier distribution calculation unit calculates a charge carrier distribution model inside the active material particle on the basis of a current value related to the secondary battery.

### [Supplementary Note 6]

The information processing apparatus according to Supplementary note 5, in which
the intra-active material charge carrier distribution model is updated by
inserting a charge carrier into a void region nearest to a surface of the active material particle among void regions of the active material particle at a time of charging the secondary battery, and
extracting a charge carrier in order from a charge carrier nearest to a surface of the active material particle among charge carriers existing in the active material particle at a time of discharging the secondary battery.

### [Supplementary Note 7]

The information processing apparatus according to any one of Supplementary notes 1 to 6, in which
the hysteresis variable calculation unit calculates the hysteresis variable on the basis of a distance by which a charge carrier moves inside the active material particle during charging and discharging of the secondary battery.

### [Supplementary Note 8]

The information processing apparatus according to any one of Supplementary notes 1 to 7, in which
the first charge-discharge history state is a state in which the secondary battery is charged to be adjusted to any charge amount from a state in which a charge amount is 0%, and
the second charge-discharge history state is a state in which the secondary battery is discharged to be adjusted to any charge amount from a state in which a charge amount is 100%.

### [Supplementary Note 9]

The information processing apparatus according to any one of Supplementary notes 1 to 8, further including:
a data acquisition unit that acquires a measured value of at least one of a current or a voltage of the secondary battery.

### [Supplementary Note 10]

The information processing apparatus according to any one of Supplementary notes 1 to 9, in which
the first impedance is a value estimated from measurement data in the first charge-discharge history state, and
the second impedance is a value estimated from measurement data in the second charge-discharge history state.

### [Supplementary Note 11]

The information processing apparatus according to any one of Supplementary notes 1 to 10, in which
the impedance calculation unit calculates an impedance of the secondary battery on the basis of a degradation coefficient related to a degradation state of the secondary battery.

### [Supplementary Note 12]

An impedance estimation method including:
a step of calculating, by an intra-active material charge carrier distribution calculation unit, a charge carrier distribution inside an active material particle included in a secondary battery;
a step of calculating, by a hysteresis variable calculation unit, a hysteresis variable representing a voltage characteristic depending on a charge-discharge history of the secondary battery on the basis of the charge carrier distribution; and
a step of calculating, by an impedance calculation unit, an impedance of the secondary battery on the basis of a first impedance in a first charge-discharge history state, a second impedance in a second charge-discharge history state, and the hysteresis variable.

### [Supplementary Note 13]

A program capable of causing a processing circuit to:
calculate a charge carrier distribution inside an active material particle included in a secondary battery;
calculate a hysteresis variable representing a voltage characteristic depending on a charge-discharge history of the secondary battery on the basis of the charge carrier distribution;
calculate an impedance of the secondary battery on the basis of a first impedance in a first charge-discharge history state, a second impedance in a second charge-discharge history state, and the hysteresis variable; and
calculate a voltage of the secondary battery on the basis of an impedance of the secondary battery.

What is claimed is:

1. An information processing apparatus comprising:
an intra-active material charge carrier distribution calculation unit that calculates a charge carrier distribution inside an active material particle included in a secondary battery;
a hysteresis variable calculation unit that calculates a hysteresis variable representing a voltage characteristic depending on a charge-discharge history of the secondary battery on a basis of the charge carrier distribution; and
an impedance calculation unit that calculates an impedance of the secondary battery on a basis of a first impedance in a first charge-discharge history state, a second impedance in a second charge-discharge history state, and the hysteresis variable.

2. The information processing apparatus according to claim 1, comprising:
a voltage calculation unit that calculates a voltage of the secondary battery on a basis of an impedance of the secondary battery and a current flowing through the secondary battery.

3. The information processing apparatus according to claim 2, wherein
the voltage calculation unit calculates a voltage of the secondary battery on a basis of an equivalent circuit model in which the impedance is expressed by a resistance and an electrostatic capacitance.

4. The information processing apparatus according to claim 2, wherein
the voltage calculation unit calculates a voltage of the secondary battery on a basis of an equivalent circuit model including an overvoltage model of the secondary battery.

5. The information processing apparatus according to claim 1, wherein
the intra-active material charge carrier distribution calculation unit calculates a charge carrier distribution model inside the active material particle on a basis of a current value related to the secondary battery.

6. The information processing apparatus according to claim 5, wherein
the intra-active material charge carrier distribution model is updated by
inserting a charge carrier into a void region nearest to a surface of the active material particle among void regions of the active material particle at a time of charging the secondary battery, and
extracting a charge carrier in order from a charge carrier nearest to a surface of the active material particle among charge carriers existing in the active material particle at a time of discharging the secondary battery.

7. The information processing apparatus according to claim 1, wherein
the hysteresis variable calculation unit calculates the hysteresis variable on a basis of a distance by which a charge carrier moves inside the active material particle during charging and discharging of the secondary battery.

8. The information processing apparatus according to claim 1, wherein
the first charge-discharge history state is a state in which the secondary battery is charged to be adjusted to any charge amount from a state in which a charge amount is 0%, and
the second charge-discharge history state is a state in which the secondary battery is discharged to be adjusted to any charge amount from a state in which a charge amount is 100%.

9. The information processing apparatus according to claim 1, further comprising:
a data acquisition unit that acquires a measured value of at least one of a current or a voltage of the secondary battery.

10. The information processing apparatus according to claim 1, wherein
the first impedance is a value estimated from measurement data in the first charge-discharge history state, and
the second impedance is a value estimated from measurement data in the second charge-discharge history state.

11. The information processing apparatus according to claim 1, wherein
the impedance calculation unit calculates an impedance of the secondary battery on a basis of a degradation coefficient related to a degradation state of the secondary battery.

12. An impedance estimation method comprising:
a step of calculating, by an intra-active material charge carrier distribution calculation unit, a charge carrier distribution inside an active material particle included in a secondary battery;
a step of calculating, by a hysteresis variable calculation unit, a hysteresis variable representing a voltage characteristic depending on a charge-discharge history of the secondary battery on a basis of the charge carrier distribution; and
a step of calculating, by an impedance calculation unit, an impedance of the secondary battery on a basis of a first impedance in a first charge-discharge history state, a second impedance in a second charge-discharge history state, and the hysteresis variable.
